(19) United States
(12) Patent Application Publication
(10) Pub. No.: US 2010/0321874 A1
(43) Pub. Date: Dec. 23, 2010

(54) COMPUTER SERVER CHASSIS

(76) Inventors: Neeloy Bhattacharyya, North Las Vegas, NV (US); Tim Byrd, Goffstown, NH (US)

Correspondence Address: STETINA BRUNDA GARRED & BRUCKER, 75 ENTERPRISE, SUITE 250, ALISO VIEJO, CA, 92656, US

(21) Appl. No.: 12/817,989

(22) Filed: Jun. 17, 2010

Related U.S. Application Data
(60) Provisional application No. 61/218,357, filed on Jun. 18, 2009.

(51) Int. Cl. H05K 7/20; G06F 19/00; G01F 1/56; G05D 23/19

(52) U.S. Cl. 361/679.5; 361/679.46; 702/45; 165/288; 702/58

(57) ABSTRACT

An expandable server housing having one or more server chassis stacked upon each other and one intake plenum and one exhaust plenum disposed on opposite sides of the stacked server chassis is disclosed. Each server chassis may have two or more fans predominately controlling airflow rate through a zone of the server chassis. Also, a method and system determining fan failure regardless of blockage of air path.

### CROSS-REFERENCE TO RELATED APPLICATIONS

This application relates to and claims the benefit of U.S. Provisional Application No. 61/218,357 filed Jun. 18, 2009 and entitled Improved Computer Server Chassis, the entire content of which is wholly incorporated by reference herein.

### STATEMENT RE: FEDERALLY SPONSORED RESEARCH/DEVELOPMENT

Not Applicable

### BACKGROUND

The present invention relates to a scalable server housing, an energy efficient cooling system and a method for distinguishing fan failure versus air blockage.

In prior art server housings, a plurality of server chassis may be mounted to the server enclosure. Each of the server chassis has its own intake plenum and exhaust plenum for cooling which does not interact with the cooling system of other server chassis in an integratable way. As a result, prior art server chassis have limited scalability to either add additional server chassis to the enclosure or to remove server chassis from the enclosure.

Additionally, in prior art server chassis, the server chassis will have two or more fans that spin at the same speed to flow air through the server chassis to cool down the electronic components within the server chassis. Unfortunately, this is an inefficient use of energy.

Also, the fans within the server chassis which cool the server chassis are monitored with respect to current and airflow. These fans are expected to produce a certain amount of airflow with a given amount of provided current. When additional current is supplied to the fans but the increase in airflow is less than expected, then such fan inefficiency may be due to potential fan failure or blockage of air within the air path. However, prior art fan monitoring systems are not capable of distinguishing whether the fan inefficiency is due to fan failure or air blockage.

### BRIEF SUMMARY

The computer equipment disclosed herein addresses the needs discussed above, discussed below and those that are known in the art.

In particular, a scalable rack mounted computer equipment is provided. The equipment may have a rack, a plurality of computer components, an air exhaust plenum and an air intake plenum. The computer components may be stacked upon each other and attached to vertical attachment points of the rack. Each of the computer components may have an airflow path between a top and bottom of the computer component. The air may flow between vertically adjacent computer components. By way of example and not limitation, air may flow from a lower computer component through a middle computer component and out of an upper computer component. Alternatively, air may flow through the air intake plenum, through an adjacent upper computer component and out of the upper computer component. Additionally, air may flow through a lower computer component through the upper computer component and out of the air exhaust plenum. Since the air exhaust plenum and air intake plenum are separate from the computer component, one or more computer components may be disposed between the air intake plenum and the air exhaust plenum for scaling the amount of computer components necessary for the computing task at hand. The air intake plenum may be disposed below the stacked computer components and the air exhaust plenum may be disposed above the stacked computer components. Alternatively, the reverse configuration is also contemplated.

An energy efficient cooling computer component is disclosed herein. The energy efficient computer component has a plurality of fans which control airflow through a plurality of zones. Based on the cooling requirement for each of the zones, each of the fans spin at a different speed thereby flowing a different amount of air through their respective zone. Accordingly, when a local area within the server chassis requires additional cooling, the zone of that increased heat area receives increased airflow. The other zones to the extent possible are left unaffected. As such, only the fan with the effected heat area requires additional energy.

A method for determining fan failure despite the existence of air flow clogging as disclosed. A calibration line curve is a data set or function which plots airflow blockage percentage on the x axis and current on the y axis. The calibration curve line is determined (1) for each chassis since each chassis will or may have different airflow characteristics and (2) for a range of fan speeds (e.g., fan blade rotations per minute, etc.). During operation, after airflow blockage occurs, the airflow blockage percentage due to the occurrence of the airflow blockage is determined. Steady state cooling is achieved by increasing power or current to the fan. The current applied to the fan is determined. If the current is above the calibration curve line for the determined airflow blockage percentage, then fan failure is likely. If the current is below the calibration curve line for the determined airflow blockage percentage, then cooling inefficiency is probably due to airflow blockage and not fan failure.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a perspective view of a server housing having a plurality of server chassis stacked upon each other and a single intake plenum and a single exhaust plenum disposed on opposite sides of the stacked server chassis;

FIG. 2 is a perspective view of the server chassis illustrating a plurality of fans controlling airflow through a respective plurality of zones;

FIG. 3 is a side cross sectional view of the server chassis shown in FIG. 2 illustrating airflow through the server chassis;

FIG. 4 is a perspective view of the intake plenum;

FIG. 5 is a perspective view of the exhaust plenum;

FIG. 6 is a top cross sectional view of the server chassis shown in FIG. 2;

FIG. 7 is a schematic of a system for determining whether cooling inefficiency is due to potential fan failure or airflow blockage; and

FIG. 8 is a graph of current as a function of percentage airflow blockage which defines a calibration curve line.

### DETAILED DESCRIPTION

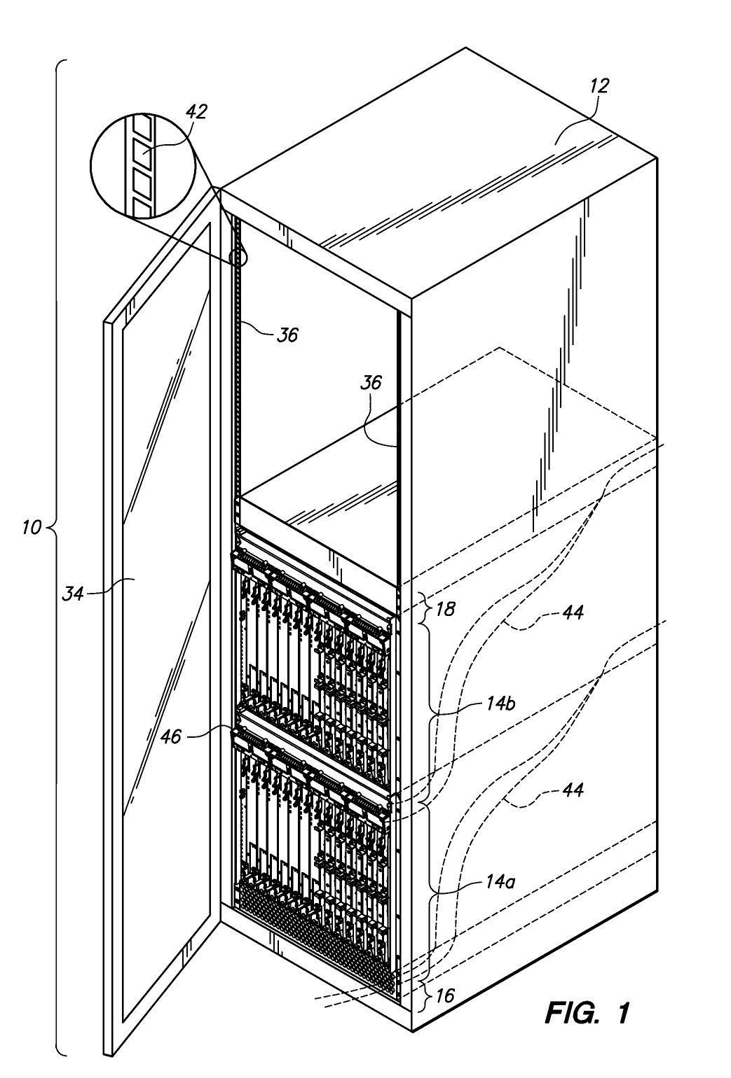

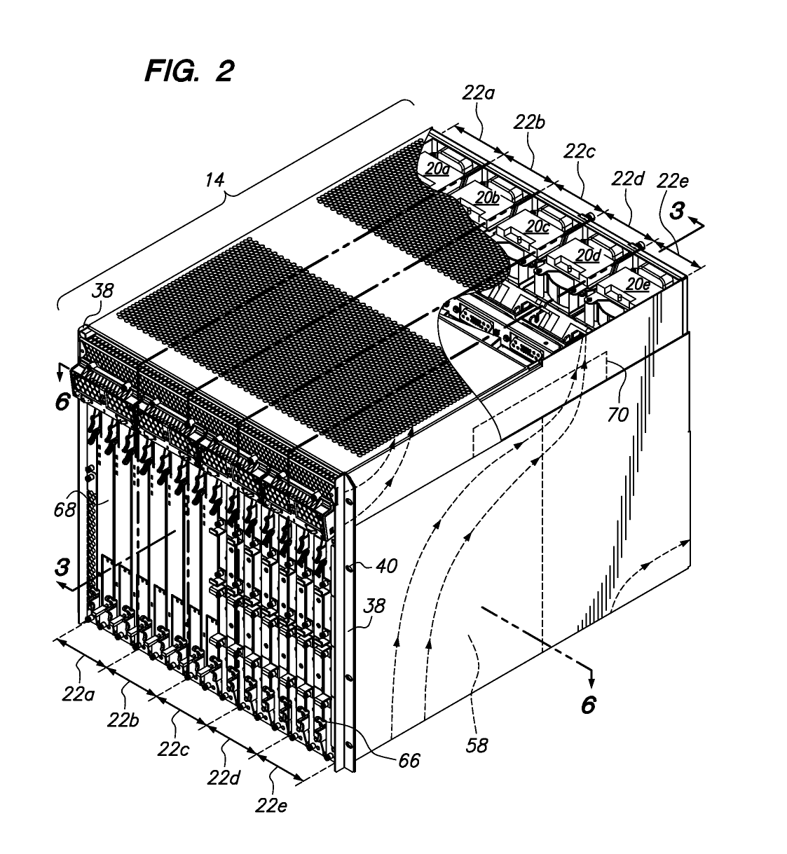

Referring now to FIG. 1, a server housing 10 is shown. The server housing 10 comprises an enclosure 12. One or more server chassis 14 is mountable to the enclosure 12 with an intake plenum 16 and exhaust plenum 18 disposed on opposed upper and lower sides of the one or more stacked server chassis mounted to the enclosure 12. The server capabilities are expandable or reconfigurable after setup by inserting additional or removing server chassis 14 between the intake plenum 16 and the exhaust plenum 18. Additionally, each server chassis 14 may have a plurality of fans 20a-e, as shown in FIG. 2. Each of the fans 20a-e may independently increase or decrease an amount of air flowing through a particular zone within the server chassis 14 to efficiently increase airflow through a particular zone when needed and decrease airflow through a particular zone 22a-e when not needed. Moreover, each of the fans 20a-e is set to a particular fan speed based on a temperature differential at an air intake 24 and exhaust 26 of the server chassis 14. Also, each of the fans 20a-e is monitored with respect to the amount of current (via a current sensor 28) flowing to the fans 20a-e and an airflow sensor 30. Current for each of the fans 20a-e and airflow for each of the zones 22a-e are respectively monitored and compared to determine whether any inefficiencies are caused by airflow blockage (e.g., dust accumulation, etc.) versus fan failure.

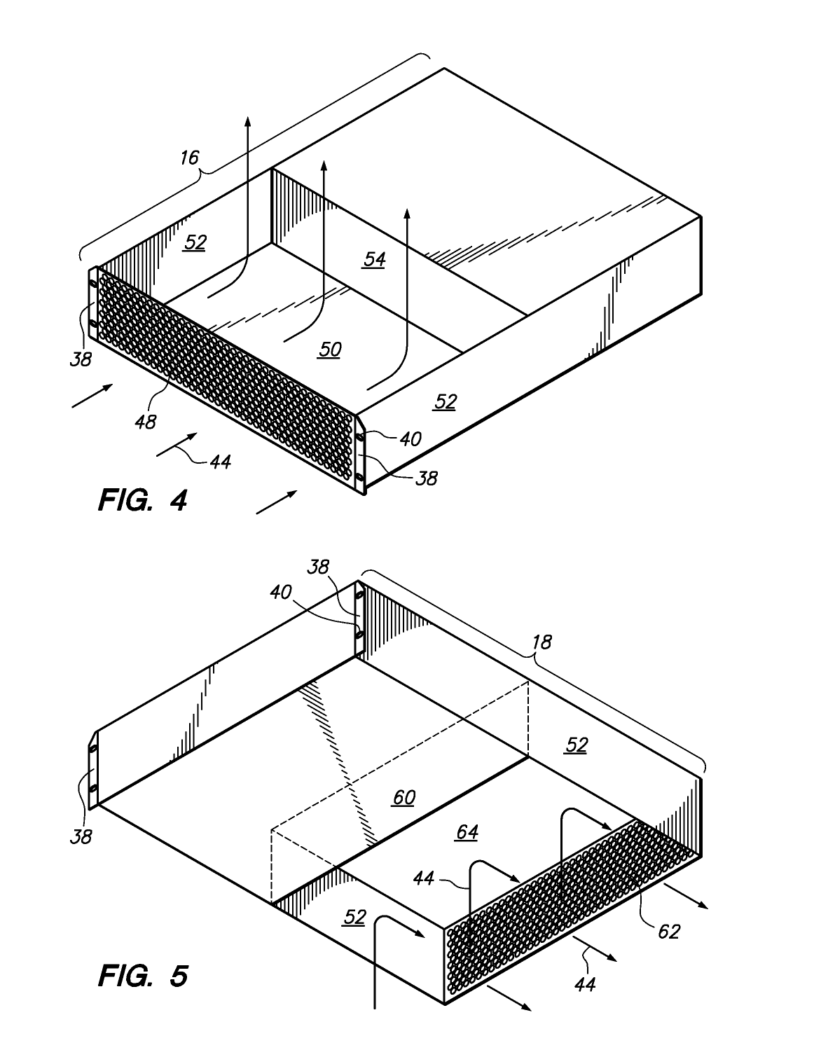

Referring now back to FIG. 1, a more detailed explanation of the overall server housing 10 will follow. The enclosure 12 may have a door 34 that may be opened or closed. The enclosure 12 may additionally have a rack 36 for mounting one or more of the server chassis 14 to the enclosure 12 and also mounting the intake plenum 16 and the exhaust plenum 18. Each of the server chassis 14 (see FIG. 2), intake plenum 16 (see FIG. 4) and exhaust plenum 18 (see FIG. 5) may have flanges 38 with one or more holes 40 along a front vertical edge thereof 14, 16 and 18. The rack 36 (see FIG. 1) may also have a flange along the vertical length of the enclosure 12 with a plurality of holes 42 along its length. The intake plenum 18, exhaust plenum 18 and the server chassis 14 may be attached or mounted to the enclosure 12 through a nut and bolt connection or other connection known in the art between the flange 38 of the intake plenum 16, exhaust plenum 18 and server chassis 14 and the rack 36 of the enclosure 12. As shown in FIG. 1, preferably, the intake plenum 16 is disposed below the one or more server chassis 14 and rests on a floor (not shown) of the enclosure 12. It is preferable that the intake plenum 16 be disposed below the other server chassis 14. The server chassis 14a is butted up against the intake plenum 16. One or more server chassis 14 may be stacked upon each other as desired. After the desired number of server chassis 14 are disposed in the enclosure 12, the exhaust plenum 18 may be butted up against the upper most server chassis 14. As can be seen in FIG. 1, airflow lines 44 are shown. Air flows through the intake plenum 16 into the adjacent upper server chassis 14a and up through the server chassis 14b. The air exits the adjacent upper server chassis 14b out its backside. For the server chassis 14b, air flows through an air intake 46 of server chassis 14a, through server chassis 14b and out the backside of exhaust plenum 18.

Alternatively, it is also contemplated that the system may be reversed in that the air flows from the top down instead of bottom up as described above.

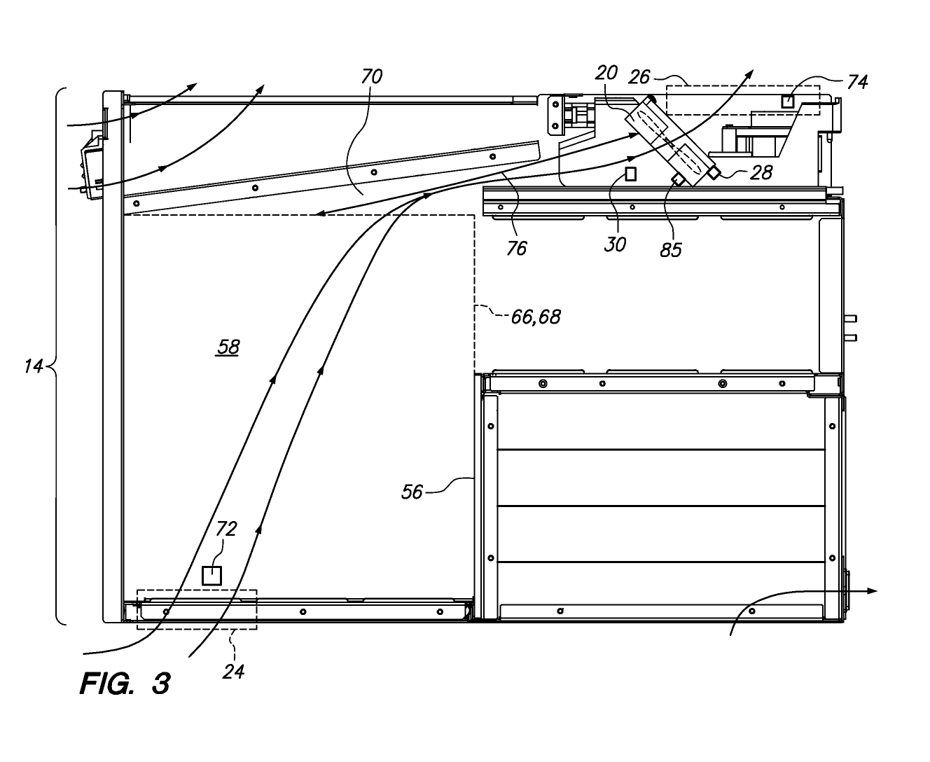

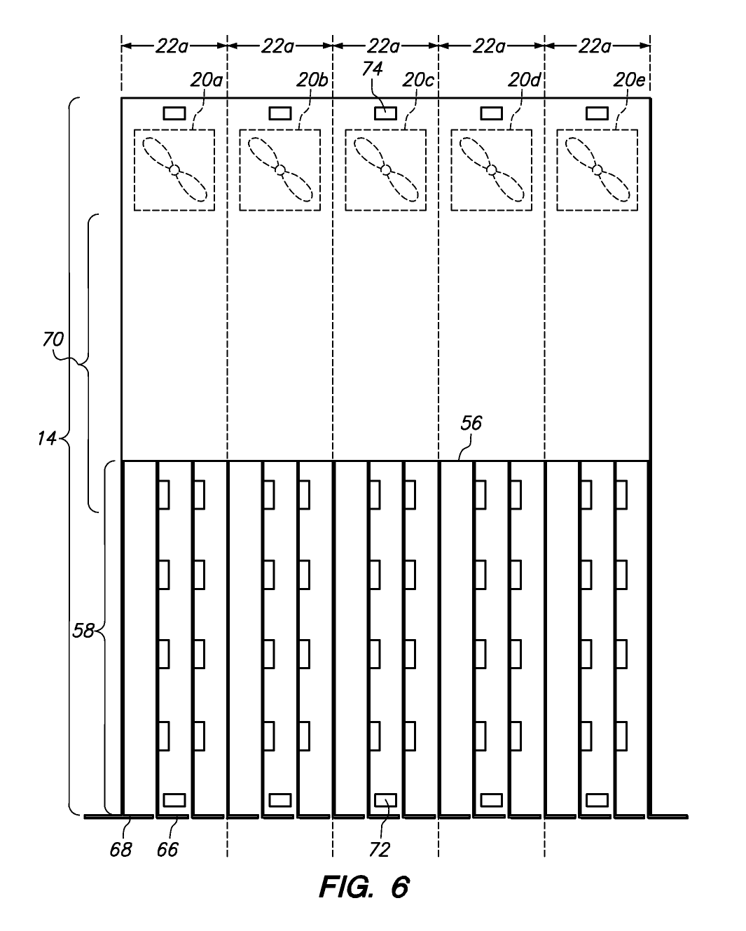

Referring now to FIG. 4, the airflow lines 44 shows the general direction of air as it flows through the intake plenum 16. The air intake plenum 16 preferably may have a perforated front plate 48 (e.g., filter) which allows air to flow through the air intake plenum 16 but prevents large particles from entering the intake plenum 16 and ultimately the server chassis 14. To guide the air through the air intake plenum 16, the air intake plenum 16 may additionally have a bottom plate 50 opposed side plates 52 and rear plate 54. The rear plate 54 is located at about the mid plane 56 (see FIGS. 3 and 6) so as to direct the air through the blade chamber 58 (see FIGS. 3 and 6) of the server chassis 14. The exhaust plenum 18 shown in FIG. 5 may have side plates 52, front plate 60 and a perforated back plate 62 as well as top plate 64. These plates 52, 60, 64 guide air in the direction of airflow lines 44, and out the back side.

Referring now to FIG. 2, each of the fans 20a-e predominately controls airflow through each of the zones 22a-e, respectively. There is some amount of mixing of air between adjacent zones 22a-e after the air exits the blade chamber 58 and enters a mixing chamber 70 to mitigate dead zones in case of fan failure as discussed below. As can be seen from FIG. 2, each of the zones 22a-e is comprised of one or more blades 66 and/or filler plates 68. These blades 66 and filler plates 68 slide through the front side of the server chassis 14 and are positionable within the blade chamber 58 (see FIG. 3). A cross sectional top view of the server chassis is shown in FIG. 6. Air flows between each of the filler plates 58 and blades 66 in a general up and out direction. Since the fan 20 is pulling air through the server chassis 14, the air is predominately drawn from the intake 24 (see FIG. 3), through the fan 20 (see FIG. 3) and out the exhaust 26 (see FIG. 3). In the blade chamber 58, the air is not mixed with air between adjacent filler plates 68 and blades 66. Rather, after the air has passed beyond the filled plates 68 and blades 66, the air enters the mixing chamber 70 in which the similarity or difference in speed of each of the fans 20a-e determines the amount of air mixing that occurs between zones 22a-e.

Each of the fans 20a-e may be independently controlled by a temperature difference reading which measures the amount of heat absorbed by the air from the blades 66 within a particular zone 22a-e. The blade is an electronic circuit board, processor, etc. which has one or more electronic components and generates heat. The filler plate 68 has a substantially similar packaging configuration as that of the blade 66. The filler plate 68, as shown in FIG. 6, has a front plate 69 which covers one of the slots within the server chassis 14. An extension plate 67 extends to the mid plane 56. An air intake temperature sensor 72 may be positioned at the intake 24 of the server chassis 14. Also, an air exhaust temperature sensor 74 may be positioned at the exhaust 26 of the server chassis 14. A set of air intake and exhaust temperature sensors 72, 74 is positioned within each zone 22a-e of each server chassis 14. Based on the temperature difference as measured by the air intake and exhaust temperature sensors 72, 74, the speed of the fan is adjusted. As the temperature difference increases, such increase indicates that one or more blades 66 within a zone 22a-e may be overheating and requires additional cooling. As a result, the fan 20a-e of that zone 22a-e is spun at a higher rate to increase airflow through such zone 22a-e for the purposes of cooling the blades 66 within that zone 22a-e. Conversely, as the temperature difference decreases, such decrease indicates that one or more of the blades 66 within a zone 22a-e requires less cooling. As a result, the fan 20a-e of that zone 22a-e is spun at a lower rate to decrease airflow through such zone 22a-e for the purposes of reducing energy requirement of the server chassis 14.

During operation, each server chassis 14 may comprise a different combination of filler plates 68 and blades 66 disposed within the blade chamber 58, as shown in FIG. 6. Due to the varying heating requirements of the blades 66 within the blade chamber 58, each of the fans 20a-e may force air through their respective zones 22a-e at different rates. Each of the fans 20a-e spin at a particular speed until a steady state is achieved. The appropriate amount of heat generated by the blades 66 within each of the zones 22a-e is removed based on the amount of air flowing through the zones 22a-e. As the load or computer processing requirement changes, the amount of heat generated by each of the blades 66 varies over time. Some blades 66 generate more heat requiring more airflow to cool down such blades 66. While other blades 66 require less airflow due to the reduction in computer processing. By way of example and not limitation, if one or more blades 66 within a particular zone 22a-e is overheating such as zone 22c, then the temperature sensors 72, 74 will measure an increased temperature differential. The fan 20c will increase in speed to increase air flowing through the zone 22c. As a result, air flowing through adjacent zones 22b, d is redirected into zone 22c at the mixing chamber 70. This increases the amount of air flowing through the zone 22c, but also reduces the amount of air that flows through the zones 22b, d. Since zones 22b, d were previously at a steady state situation, the reduction of airflow through the zones 22b, d will cause an increase in temperature differential as measured by temperate sensors 72, 74 within those zones 22b, d. This will increase the speed of the fans 20b, d to accommodate the reduced airflow through zones 22b, d and the increased fan speed of fan 20c. As the cooling requirements of the blades 66 within each of the zones 22a-e changes, the temperature differential as measured by the sensors 72, 74 changes and the fans 20a-e reacts (i.e., fan speed increases or decreases) to those changes. Most importantly, the fans 20a-e work harder only when necessary on a zone by zone basis within the server chassis 14. As a result, this produces an efficient energy server.

It is also contemplated that the air intake temperature sensor 72 may be located at different areas within the server housing 10. By way of example and not limitation, the air intake temperature sensor 72 may measure ambient temperature which may be a close estimate to the temperature at the intake 24 of the server chassis 14 or at least a constant difference to the temperature of the intake 24 of the server chassis 14. Alternatively, a single air intake temperature sensor 72 may be located adjacent the enclosure 12 and used to calculate the temperature differential with respect to the air exhaust temperature sensor 74 of each of the zones 22a-e for determining the fan speed of the fans 20a-e.

The mixing chamber 70, as shown in FIG. 3 defines a distance 76 between the fan 20 and the blades 66 or filler plates 68. This distance 76 is sufficiently short such that each of the fans 20a-e predominately affects air flowing respectively through zones 22a-e and yet allows mixing of air between immediately adjacent zones 22a-e in the mixing chamber 70. This allows each of the fans 20a-e to flow a different amount of air through each of the zones 22a-e. Also, in the event one or more of the fans 20a-e completely fails, adjacent fans may cause air to flow at least some air through the zone 22a-e with the failed fan. The mixing chamber 70 extends across all of the zones 22a-e. It is contemplated that each of the server chassis 14 may have two or more zones 22, and not necessarily only five (5) zones 22a-e. Nonetheless, despite the number of zones 22a-e in each of the server chassis 14, the zones 22 are interconnected at the mixing chamber 70. Alternatively, it is contemplated that the server chassis 14 may have a plurality of zones 22 but in all instances at least two (2) adjacent zones 22 are in fluid communication with each other at a mixing chamber 70. The reason that the mixing chamber 70 interconnects the adjacent zones 22 is to prevent any dead zones. If one fan 20 were to fail, the fan 20 of the adjacent zone 22 would predominately flow air through its zone 22 but also promote airflow through the zone 22 with the failed fan 20.

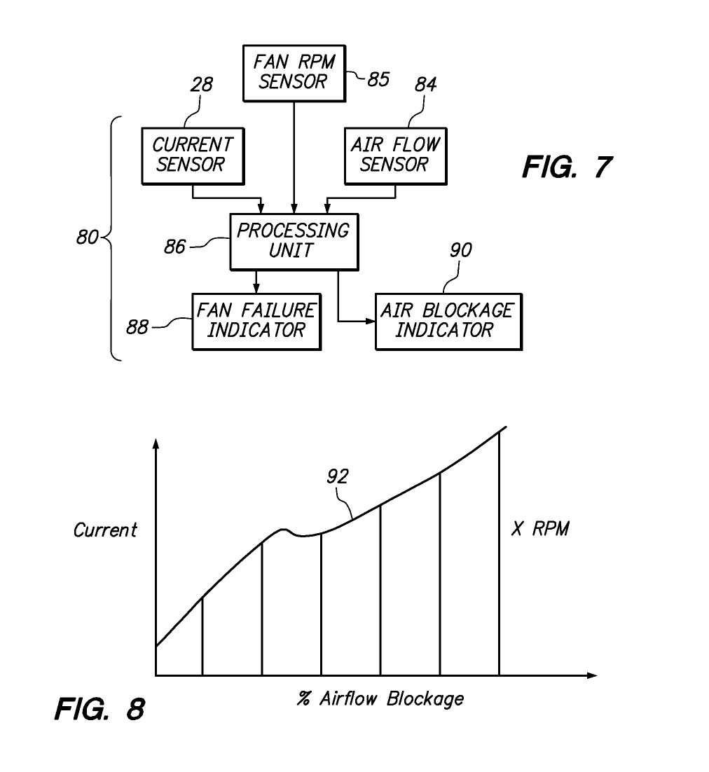

Referring now to FIG. 7, a system 80 for determining fan failure regardless of air flow blockage is shown or determining whether cooling inefficiency in a server chassis 14 is due to potential fan failure or airflow blockage. Each of the zones 22a-e is fitted with a current sensor 28, airflow sensor 84 and a fan RPM sensor 85. The locations of the current sensor 28, fan RPM sensor 85 and airflow sensor 84 are shown in FIG. 3. The sensed current, sensed fan speed and sensed airflow are sent to a processing unit 86 which determines whether any fan inefficiency is due to a potential fan failure or blockage of air. After the processing unit 86 determines whether the fan inefficiency is due to fan failure or blockage of air, then the appropriate indicator, namely, fan failure indicator 88 or air blockage indicator 90 is activated. The fan failure indicator 88 and/or the air blockage indictor 90 may be a light emitting diode, text message, etc.

In particular, during normal operation of the server chassis 14, each of the blades 66 are cooled with cooler air passing over the electronic components of the blades 66. This forced cooling is accomplished by the fans 20a-e for each of the zones 22a-3 independently. As the current supplied to the fans 20a-e increases, the air flows through the zones 22a-e increases. Conversely, as the current supplied to the fans 20a-e decreases, the air flows through the zones 22a-e decreases. The current supplied to the fans 20a-e increases and decreases until a steady state cooling is achieved. The amount of heat generated by the electronic components of the blades 66 are removed from the surrounding area by passing the cooler air over the electronic components until the electronic components of the blade 66 operate within its normal temperature range. As the server is operating, air flow blockage may occur. This air flow blockage may be gradual through the gradual accumulation of dust on the perforated front plate 48 of the intake plenum 16 or other intake apertures. Alternatively, the air flow blockage may be caused by a large piece of object (e.g. paper, etc.) that blocks air flow through the server chassis 14. When air flow blockage occurs, the rate (eg LFM) or air flow rate through one or more of the zones 22a-e is reduced and the associated fan RPM is also reduced. The air flow sensor 84 senses and determines the reduced air flow rate based on the reduced fan RPM. The processing unit 86 now calculates or determines the air flow blockage percentage as calculated by the following formula. One (1) minus the air flow rate without airflow blockage at the fan RPM during steady state cooling over air flow rate after blockage multiplied by one hundred (100). The processing unit 86 then retrieves a calibration curve (i.e. current of fan as a function of air flow blockage percentage) for the fan speed of the fan at steady state cooling. The processing unit then increases the fan RPM by increasing power or current to the fan until the air flow rate is or achieves a steady state cooling. The current applied to the fan 20a-e is sensed through the current sensor 28. Thereafter, the processing unit 86 determines whether the current applied to the fan 20a-e is above the calibration curve line 92 (see FIG. 8) which indicates potential fan failure or below the calibration curve line 92 which indicates that the fan is not failing but the cooling inefficiency of the zone 22a-e is due to air flow blockage. Either the fan failure indicator 88 or the air blockage indicator 90 is activated as appropriate.

The calibration curve line 92 is shown in FIG. 8 which is a graph of percentage air flow blockage and current. The calibration curve line 92 is determined empirically through a series of tests. Each server chassis 14 may have a different air flow characteristic. For each zone 22a-e, a different calibration curve line 92 is empirically determined unless the zones 22a-e behave with substantially similar air flow characteristics. Then, as assumption is made that the airflow characteristics of each of the zones 22a-e are identical. The following steps explain how to empirically gather the data to plot the calibration curve line 92. Initially, the fans 20a-e are or one of the fans 20a-e is set to an RPM X. The air flow path through the zone 20a-e is cleared such that there is zero percent air flow blockage. With the fan speed set to X RPM and zero percent air flow blockage, the current sensor 28 measures the current being applied to the fan 20a-e. This is your first data point. Next, the air flow path through the zone 22a-e is physically blocked by a certain percentage. By way of example and not limitation, ten percent. Since the air flow is blocked, the fan speed will decrease due to the vacuum created in the server chassis 14. This data set being collected is for the calibration curve line 92 at X RPM. The fan 20a-e is supplied with additional current or power to increase the fan speed or fan RPM back up to X RPM. The current sensor 28 senses the current being applied to the fan 20a-e for X RPM with the increased air flow blockage. This is your second data point. The above steps of increasing the percentage air flow blockage, increasing fan speed, and determining the new current being applied to the fan 20a-e is repeated until a full range of air flow blockage percentages are obtained. By way of example and not limitation, the calibration curve line 92 may be determined from zero percent air flow blockage to one hundred percent air flow blockage. However, it is also contemplated that a smaller range of air flow blockage percentages could be just as useful. By way of example and not limitation, the range may be from zero percent to fifty percent since the air blockage indicator 90 may send a message to a technician that the air flow blockage is too great after 50% and that any sustained operation of the fan 20a-e at this high level of air flow blockage is unacceptable and will eventually cause fan failure. After the calibration curve line 92 is determined for a particular RPM X, the fan speed or RPM is changed and a new calibration curve line is obtained for that new fan RPM. The calibration curve line 92 is determined for a range of fan RPMs. By way of example and not limitation, the range may be from the minimum fan speed to a maximum fan speed or the fan speed at which the maximum permitted acoustic sound level is reached. If the maximum permitted acoustic sound level is reached, then the processing unit 86 may a send a message to the technician that the fan 20a-e is creating too much noise in its environment.

The above description is given by way of example, and not limitation. Given the above disclosure, one skilled in the art could devise variations that are within the scope and spirit of the invention disclosed herein, including various ways of attaching the intake plenum 16, the exhaust plenum 18 and the server chassis 14 to the rack 36. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A scalable rack mounted computer equipment, the equipment comprising:
a rack having a plurality of vertical attachment points;
a plurality of computer components stacked upon each other and attached to the vertical attachment points, each of the computer components having an airflow path between a top and bottom of the computer component, the air flow paths of vertically adjacent computer components being in fluid communication with each other;
an air exhaust plenum attached to the vertical attachment point and disposed either above the upper most computer component with an air flow path of the air exhaust plenum in fluid communication with the airflow path of the upper most computer component or below the lower most computer component with the airflow path of the air exhaust plenum in fluid communication with the airflow path of the lower most computer component;
an air intake plenum attached to the vertical attachment point and disposed on an opposite side of the stacked computer components from the air exhaust plenum with an airflow path of the air intake plenum in fluid communication with either the airflow path of the lower most computer component or the airflow path of the upper most computer component.

2. The equipment of claim 1 wherein the air exhaust plenum is disposed above the stacked computer components, and the air intake plenum is disposed below the stacked computer components.

3. The equipment of claim 2 wherein the air intake plenum flows from a front side of the air intake plenum to a top side of the air intake plenum, and the air exhaust plenum flows from a bottom side of the air exhaust plenum to a back side of the air exhaust plenum.

4. An energy efficient cooling system for a computer component comprising:
an entrance;
a plurality of isolated air pathways, each of the air intake pathways being in fluid communication with the entrance, the plurality of isolated air pathways grouped into two or more zones;
a mixing chamber in fluid communication with exits of the plurality of isolated air pathways;
a plurality of fans in fluid communication with the mixing chamber, the plurality of fans directed toward the isolated air pathways for drawing air from the isolated air pathways through the mixing chamber through the fan, each fan predominantly affecting airflow through at least one zone;
wherein a distance between the fans and the exits of the plurality of isolated air pathways and a volume of the mixing chamber is balanced such that induced airflow by one of the fans affects air flow through the at least one zone yet allows sufficient mixing of air with an adjacent zone.

5. The energy efficient cooling system of claim 4 further comprising:
a controller for independently regulating fan speeds based on a sensed temperature difference at an entrance and exit of the computer component.

6. The energy efficient cooling system of claim 5 further comprising an entrance temperature sensor for measuring a temperature at the entrance of the computer component and an exit temperature sensor for measuring a temperature at the exit of the computer component.

7. The energy efficient cooling system of claim 5 wherein a temperature sensor measures ambient temperature, the temperature sensed by the temperature sensor approximates the temperature at the entrance of the computer component.

8. A method of determine whether cooling inefficiency of a server chassis is due to potential fan failure or airflow blockage, the method comprising the steps of:
providing a calibration curve line for a range of fan speeds, the calibration curve line is current as a function of percentage airflow blockage at a particular fan speed;
after an occurrence of airflow blockage, sensing a reduced airflow;
determining a percentage airflow blockage;
increasing fan speed until steady state cooling is achieved;
sensing current or power to the fan after the increasing step;
indicating potential fan failure if the current sensed during the sensing current step is above the calibration curve line; and
indicating airflow blockage with an efficient fan if the current sensed during the sensing current step is below the calibration curve line.
